(19) United States
(12) Patent Application Publication
(10) Pub. No.: US 2004/0188739 A1
(43) Pub. Date: Sep. 30, 2004

(54) Semiconductor device including trench capacitor and manufacturing method of the same

(76) Inventors: Keiichi Takenaka, Kanagawa-ken (JP); Itsuko Sakai, Kanagawa-ken (JP); Masaki Narita, Kanagawa-ken (JP); Tokuhisa Ohiwa, Kanagawa-ken (JP); Atsuo Sanda, Kanagawa-ken (JP); Katsunori Yahashi, Kanagawa-ken (JP)

Correspondence Address: Finnegan, Henderson, Farabow,, Garrett & Dunner, L.L.P., 1300 I Street, N.W., Washington, DC, 20005-3315, US

(21) Appl. No.: 10/752,682

(22) Filed: Jan. 8, 2004

(30) Foreign Application Priority Data
Jan. 8, 2003 (JP) P2003-001740

(51) Int. Cl. H01L 27/108

(52) U.S. Cl. 257/301

(57) ABSTRACT

A semiconductor device includes a semiconductor substrate, a trench including a narrowed portion and a main part, a diameter of the narrowed portion being coaxially smaller than a diameter of the trench at the main part, a first capacitor electrode provided in the semiconductor substrate so as to surround the trench inclusive of the narrowed portion, a capacitor insulating film provided along a surface of the first capacitor electrode, a second capacitor electrode provided inside the trench.

### CROSS-REFERENCE TO RELATED APPLICATIONS

This application is based upon and claims the benefit of priority from the prior Japanese Patent Application No. 2003-1740, filed Jan. 8, 2003, the entire contents of which are incorporated herein by reference.

### FIELD OF THE INVENTION

The present invention relates to trench capacitors to be provided in semiconductor devices. Specifically, the present invention relates to a semiconductor device including a trench capacitor and a manufacturing method of the same.

### BACKGROUND OF THE INVENTION

A semiconductor device such as a dynamic random access memory (DRAM) includes capacitors for storing memories in the form of accumulation of electric charges.

A certain minimum charge accumulation is essential to operate a memory cell accurately without performing excessive refresh operations. The capacitor for accumulating the charges is required to have a certain minimum electric capacity.

Various contrivances have been heretofore made to secure sufficient capacities of capacitors so as to prevent damages to information storage functions in an attempt to achieve higher integration and miniaturization of devices. Here, a typical example is a trench capacitor.

The trench capacitor is a capacitor which is formed three-dimensionally by use of a deep ditch (trench) provided on a silicon substrate. By forming the capacitor three-dimensionally, it is possible to secure a large area for a counter electrode of the capacitor as compared to the case of two-dimensionally forming the capacitor. The capacity of the capacitor is in proportion to the area of the counter electrode of the capacitor. Accordingly, the capacity of the capacitor is increased more as the trench is deeper. In this way, it is easy to secure the capacity of the capacitor in the event of integration.

However, the devices are further miniaturized in recent years. As a result, it is becoming more difficult to secure a prescribed capacity of a capacitor by forming a deeper trench.

A trench diameter is reduced when the devices are miniaturized. Accordingly, the capacity of the capacitor is reduced and an aspect ratio (a depth of the trench/a caliber of the trench top) is increased. In general, an etching rate of dry etching used upon formation of the trench depends largely on the number of etching sources reaching the bottom of the trench. When the aspect ratio of the trench is increased, the number of the etching sources reaching the bottom of the trench is decreased and the etching rate is thereby reduced. Such reduction in the etching rate causes a significant decrease in productivity, which constitutes a major obstacle to secure a prescribed capacity of a capacitor in a deeper trench.

To solve this problem, disclosed is a trench capacitor in which an irregular portion is formed on a trench inner wall as a different measure for increasing the area for the counter electrode of the trench (Japanese Patent Publication (Kokai) No. 2002-110942, pages 5 and 6, FIGS. 2 and 3).

One of conventional examples will be described with reference to FIGS. 1A to 1F. FIGS. 1A to 1F are cross-sectional views showing a conventional method of manufacturing a semiconductor device including a trench capacitor.

As shown in FIG. 1A, a trench 104 is formed on a silicon substrate 101 while using a silicon oxide film 102 and a silicon nitride film 103 collectively as an etching mask. Arsenic is diffused in silicon substrate 101 so as to surround a lower part of trench 104 by the solid-state diffusion method, thereby providing a first capacitor electrode 105. A silicon oxide film 106 is formed so as to cover the entire surface of trench 104, and a polysilicon film 107 is laminated thereon.

As shown in FIG. 1B, polysilicon film 107 of an upper layer and silicon oxide film 106 of a lower layer are subjected to wet etching with NH₄F. Since polysilicon film 107 has lower permeation resistance to NH₄F at grain boundaries, the etching of silicon oxide film 106 of the lower layer progresses due to permeation of NH₄F. In this way, numerous voids 108 are formed in silicon oxide film 106.

As shown in FIG. 1C, polysilicon film 107 is subjected to an overall separation process by chemical dry etching (CDE) After separation of polysilicon film 107, etching of an impurity diffusion layer which is first capacitor electrode 105 of silicon substrate 101 progresses in positions of the voids in silicon oxide film 106. Accordingly, the surface of first capacitor electrode 105 is made irregular.

As shown in FIG. 1D, silicon oxide film 106 is subjected to overall separation by wet etching with NH₄F.

As shown in FIG. 1E, a capacitor insulating film 109 is formed along first capacitor electrode 105 inside trench 104. As a second capacitor electrode, arsenic-doped polysilicon is filled into trench 104.

Second capacitor electrode 110 and an upper part of capacitor insulating film 109 are subjected to an etchback process, and an upper inner wall of trench 104 is thereby exposed. A collar oxide film 111 is formed at the exposed portion. A redundant portion of collar oxide film 111 is removed by etchback. A trench capacitor as shown in FIG. 1F is finished by filling arsenic-doped polysilicon into the upper inner wall of trench 104.

In this conventional trench capacitor, capacitor insulating film 109 has an irregular shape along the irregular inner surface of trench 104. Accordingly, the surface area of capacitor insulating film 109 is virtually increased and the electric capacity of the trench capacitor is thereby increased.

### SUMMARY OF THE INVENTION

A semiconductor device including a trench capacitor according to an embodiment of the present invention comprises a semiconductor substrate, a trench provided on the semiconductor substrate, the trench including a narrowed portion and a main part having substantially straight side walls in terms of a perpendicular cross section to a surface of the substrate, a diameter of the narrowed portion being coaxially smaller than a diameter of the trench at the main part, a first capacitor electrode provided in the semiconductor substrate so as to surround the trench inclusive of the narrowed portion, a capacitor insulating film provided along a surface of the first capacitor electrode, and a second capacitor electrode provided inside the trench, the second capacitor electrode being opposed to the first capacitor electrode through the capacitor insulating film.

Further, another aspect of the invention may comprise a semiconductor substrate, a first trench provided on the semiconductor substrate, the first trench including a narrowed portion and a main part having substantially straight side walls in terms of a perpendicular cross section to a surface of the substrate, a diameter of the narrowed portion being coaxially smaller than a diameter of the first trench at the main part, a second trench provided on the semiconductor substrate at a distance from the first trench, the second trench having substantially the same depth and substantially the same diameter as the first trench, the second trench including a narrowed portion having substantially the same diameter and being provided in substantially the same depth position as the narrowed portion of the first trench, a first capacitor electrode respectively provided in the semiconductor substrate in a position corresponding to each of the first trench and the second trench so as to surround each of the first trench and the second trench inclusive of the narrowed portion,

a capacitor insulating film respectively provided along a surface of the first capacitor electrode of each of the first trench and the second trench, and a second capacitor electrode respectively provided inside each of the first trench and the second trench, the second capacitor electrode being opposed to the first capacitor electrode through the capacitor insulating film.

Further, a method of manufacturing a semiconductor device including a trench capacitor according to an embodiment of the present invention comprise forming a mask pattern on an upper surface of a semiconductor substrate, and forming a trench on the semiconductor substrate while using the mask pattern as an etching mask, wherein forming the trench includes forming a main part of a trench by first anisotropic etching process and forming a narrowed portion in which a diameter of the main part of the trench is coaxially reduced by second anisotropic etching process in which etching conditions differ from the first anisotropic etching process.

### BRIEF DESCRIPTION OF THE DRAWINGS

FIGS. 1A to 1F are cross-sectional views showing a conventional method of manufacturing a trench capacitor in the order of processes.

FIG. 2 is a cross-sectional view showing a structure of a semiconductor device according to a first embodiment of the present invention.

FIGS. 3A to 3G are cross-sectional views showing a method of manufacturing the semiconductor device according to the first embodiment of the present invention in the order of processes.

FIG. 4 is a graph showing dependency of a silicon etching rate on an aspect ratio according to the first embodiment.

FIGS. 5A to 5D are cross-sectional views showing a method of manufacturing a semiconductor device according to a second embodiment of the present invention in the order of processes.

FIG. 6 is a graph schematically showing a relation between processing time and an etching rate in a trench formation process of the second embodiment of the present invention.

FIG. 7 is a graph schematically showing a relation between the processing time and a trench depth in the trench formation process of the second embodiment of the present invention.

FIG. 8 is a schematic drawing showing a structure of a etching system used in a third embodiment of the present invention.

FIG. 9 is a graph showing transition of luminescence intensity of F₂ relative to etching time in the third embodiment of the present invention.

FIG. 10 is a schematic drawing showing a structure of a etching system used in a fourth embodiment of the present invention.

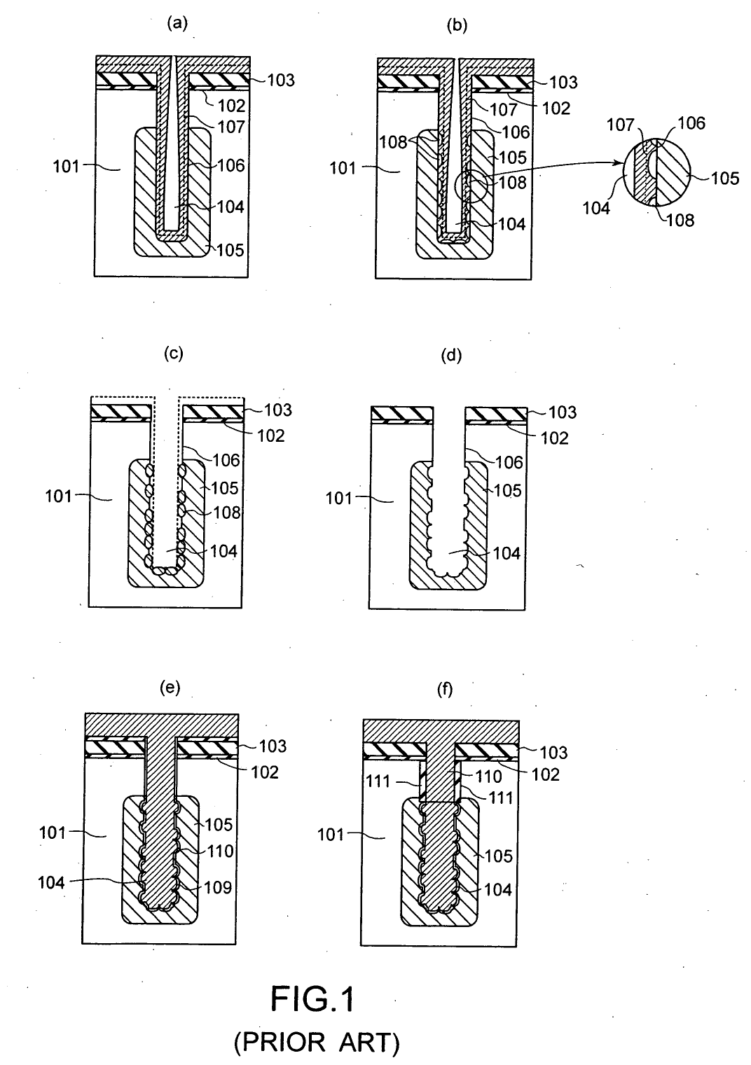

### DETAILED DESCRIPTION OF THE INVENTION

In the conventional trench capacitor provided with the irregular portion on the trench inner wall, concrete means for providing the irregular portion relies on natural formation of the irregular portion. Accordingly, it has been practically impossible to control formation of the irregular portion in a desired shape and in a desired position.

Moreover, in the case of providing the irregular portions in accordance with the conventional method, there has also been a problem when a plurality of trench capacitors are fabricated in the same semiconductor substrate that capacities of the capacitors vary due to different shapes of the irregular portions among the plurality of trench capacitors.

A semiconductor device including a trench capacitor and a manufacturing method of the same according to the embodiments of the present invention to be described below enables accurate control of the shape and position of formation of the irregular portion on the trench inner wall.

### FIRST EMBODIMENT

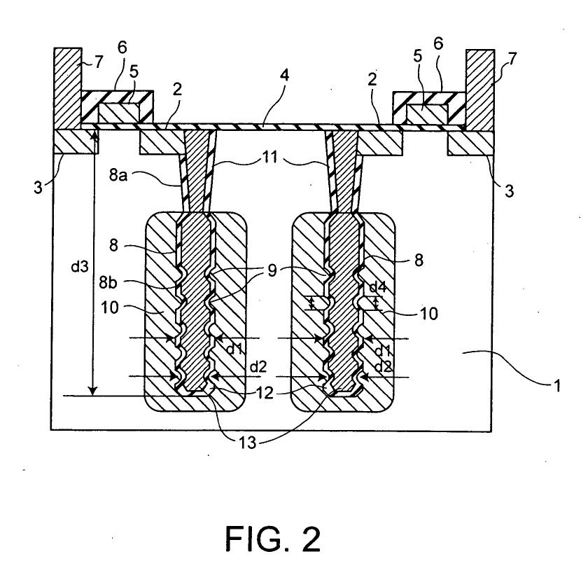

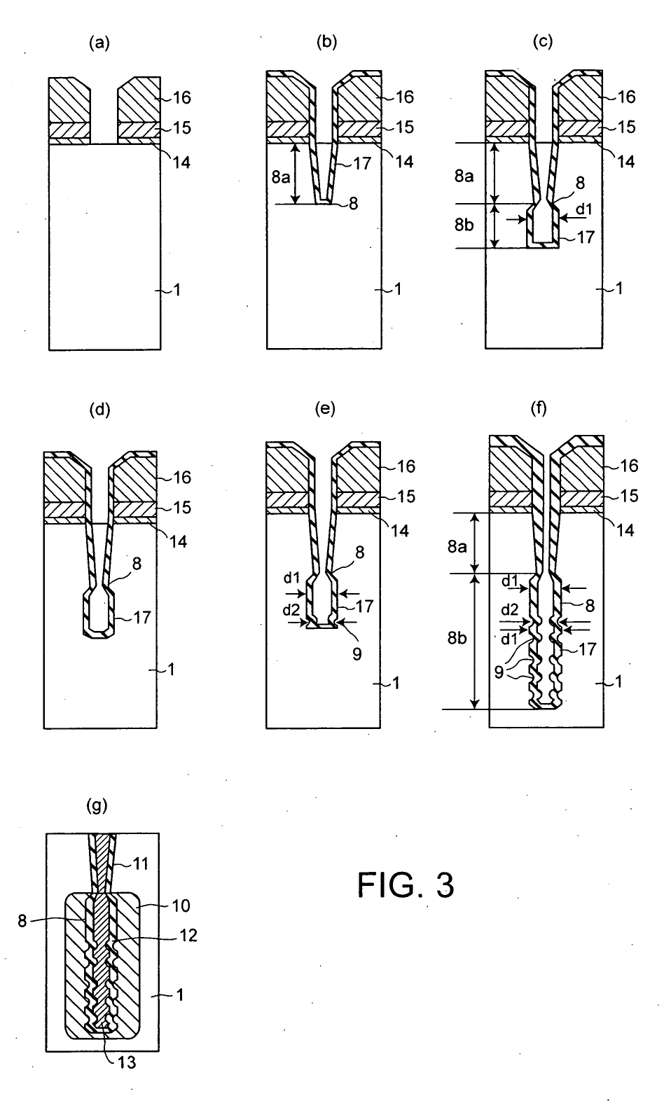

A semiconductor device including a trench capacitor and a manufacturing method of the same according to a first embodiment of the present invention will be described with reference to FIGS. 2 to 3G based on an assumption that a silicon substrate is used as a semiconductor substrate.

FIG. 2 is a cross-sectional view showing a structure of a semiconductor device including a trench capacitor according to the first embodiment of the present invention.

Source diffusion layers 2 which are first and third diffusion layers, and drain diffusion layers 3 which are second and fourth diffusion layers, are formed on an upper surface of a silicon substrate 1. Word line electrodes 5 which are first and second gate electrodes are formed on a gate oxide film 4 between source diffusion layers 2 and drain diffusion layers 3. Word line electrodes 5 are made of polysilicon or tungsten silicide, for example. Silicon nitride films 6 are formed around word line electrodes 5. The aforementioned constituents collectively constitute transistors.

Bit lines 7 are formed on drain diffusion layers 3 so as to contact drain diffusion layers 3. Meanwhile, trenches 8 which are first and second trenches are provided on source diffusion layers 2 adjacently to each other.

Trench 8 includes a tapered trench upper part 8a, and a trench lower part 8b of which an inner wall is perpendicular to the upper surface of the semiconductor substrate. Trench 8 is comprised main parts and narrowed portions. Main parts are comprised substantially straight side walls in terms of a cross section perpendicular to the substrate surface. Narrowed portions 9 are provided in one or more positions of trench lower part 8b so as to reduce diameters of trench lower part 8b coaxially with trench 8.

First capacitor electrodes 10 are formed inside silicon substrate 1 by diffusing an impurity such as arsenic so as to surround trench lower parts 8b. Collar oxide films 11 are formed on side walls of trench upper parts 8a. First capacitor electrodes 10 are avoided from being electrically connected to source diffusion layers 2.

Capacitor insulating films 12 are formed on inner wall surfaces of trench lower parts 8b so as to be aligned with surface shapes of first capacitor electrodes 10. Capacitor insulating film 12 is a thin film as a whole. Arsenic-doped polysilicon, for example, is filled in the rest of internal spaces of trenches 8 as second capacitor electrodes 13. Second capacitor electrodes 13 are electrically connected to source diffusion layers 2.

When narrowed portions 9 are provided on first capacitor electrode 10 as described above, the surface area of the capacitor electrode is increased and an electric capacity of the trench capacitor is increased.

Five narrowed portions 9 (regarding dimensions of narrowed portions 9, d2 in FIG. 2 is set to 125 nm and d4 therein is set to 30 nm) are formed in trench 8 having a depth (d3 in FIG. 2) at 8 ?m and the diameter of the main parts of trench lower part 8b (d1 in FIG. 2) at 150 nm, and then a capacity of this trench capacitor is measured. As a result, the capacity of this trench capacitor turned out to be larger by about 15% than a capacity of a trench capacitor of the same depth without formation of narrowed portions 9.

In this way, securing of sufficient accumulation of electric charges is facilitated even with the limited surface area of the trench capacitor. It is possible to achieve higher integration of the entire semiconductor device.

When the semiconductor device according to this embodiment of the invention includes a plurality of trench capacitors, at least a plurality of adjacent trench capacitors out of all the plurality of trench capacitors have substantially the same depth, and such a plurality of adjacent trench capacitors have substantially the same trench diameter (d1 in FIG. 2) at substantially the same depth position of the trenches Narrowed portions 9 are formed substantially in the same diameter (d2 in FIG. 2) at substantially the same depth position of the trenches, and the numbers of narrowed portions are inevitably the same between these trenches. As a result, the surface area of the capacitor electrode does not vary widely among the plurality of trench capacitors. The variation of the electric capacity of the trench capacitors in this embodiment is substantially the same as that of the trench capacitors where no narrowed portions 9 are formed. This is one of effects of the semiconductor device including a trench capacitor according to the first embodiment of the present invention. With this structure, it is possible to provide a semiconductor device including a highly reliable trench capacitor.

FIGS. 3A to 3G are cross-sectional views showing a method of manufacturing the semiconductor device including a trench capacitor according to the first embodiment of the present invention in the order of processes.

A silicon oxide film 14 in a film thickness of 4.5 nm is formed on silicon substrate 1 by the thermal oxidation method. A silicon nitride film 15 in a film thickness of 220 nm and a silicon oxide film 16 in a film thickness of 1400 nm are laminated on silicon oxide film 14 by the chemical vapor deposition (CVD) method. A resist film is coated thereon, and then a resist pattern is formed by a photolithography process. Using this resist pattern as an etching mask, silicon oxide film 16, silicon nitride film 15, and silicon oxide film 14 are etched by the reactive ion etching (RIE) method until silicon substrate 1 is exposed as shown in FIG. 3A.

Using silicon oxide film 16 as an etching mask, trench upper part 8a is formed by etching down to a predetermined depth by the RIE method. Trench upper part 8a is formed into a forward tapered shape as shown in FIG. 3B. Mixed gas containing 230 SCCM of HBr, 21 SCCM of O₂, and 35 SCCM of NF₃, for example, is used as etching gas. Regarding etching conditions, a pressure is set to 150 mTorr and excitation power is set to 900 W, for example. As the etching progresses, an etching deposit 17 composed of a reactant of silicon with the etching gas is generated and deposited on the etching mask and inside trench 8.

After formation of the tapered trench upper part 8a, the process moves to formation of trench lower part 8b. Etching conditions are changed, and then etching is performed so as to form main parts on the side wall of trench 8 (the trench diameter in this process is denoted as d1) as shown in FIG. 3C. The main part is a portion where the side wall becomes substantially straight in terms of a cross section perpendicular to the surface of silicon substrate 1. Mixed gas containing 300 SCCM of HBr, 22 SCCM of O₂, and 7 SCCM of SF₆, for example, is used as the etching gas. Regarding the etching conditions, the pressure is set to 200 mTorr and the excitation power is set to 1600 W, for example. This process will be hereinafter referred to as a main part formation process.

After this main parts formation process, mixed gas containing 300 SCCM of HBr, 25 SCCM of O₂, and 7 SCCM of SF₆, for example, is used as the etching gas. Regarding the etching conditions, the pressure is set to 200 mTorr and the excitation power is set to 1600 W, for example. The etching is continued for 20 seconds. The etching conditions described above are only required to permit more deposition of etching deposit 17 on the inner wall of trench 8 as compared to the etching conditions in the main part formation process. As shown in FIG. 3D, under these etching conditions, etching deposit 17 functioning as a protective film to the etching tends to be deposited more on a peripheral part than a central part at the bottom of the trench. As a result, an etching rate at the peripheral part becomes slower than the central part at the bottom of the trench, whereby the etching progresses such that the trench diameter becomes narrower than the above-mentioned trench diameter d1. This process will be hereinafter referred to as a narrowed portion formation process.

Next, the above-described main part formation process is performed again. The etching conditions are changed again to the etching conditions for the main part formation process (300 SCCM of HBr, 22 SCCM of O₂, and 7 SCCM of SF₆, the pressure at 200 mTorr, and the excitation power at 1600 W). Accordingly, the etching is performed so as to form the main part which is substantially perpendicular to silicon substrate 1. As shown in FIG. 3E, narrowed portion 9 having trench diameter d2 is formed coaxially with trench 8. After formation of narrowed portion 9, the trench diameter comes back to d1 again. It is apparent that the etching progresses while maintaining trench diameter d1, in other words, while continuing formation of the main part.

FIG. 3F shows the trench after repeating the set of the narrowed portion formation process and the main part formation process for five times. In response to insertion of the narrowed portion formation process for five times, narrowed portions 9 are formed in five positions and the surface area of the trench is thereby increased. Here, description has been made on an example of forming the narrowed portions in five positions. However, the number of the narrowed portions will not be limited to five. It is possible to obtain trench 8 having a desired surface area by changing the number of the narrowed portions. These are the process for forming trench 8.

The manufacturing process after the process for forming trench will be described with reference to FIG. 3G. Etching deposit 17 deposited inside the trench and on silicon substrate 1 is removed by wet etching or the like. First capacitor electrode 10 is formed in the state that the upper part of trench 8, where collar oxide film 11 shown in FIG. 2 is supposed to be formed, is covered with a mask. First capacitor electrode 10 is formed by the solid-state diffusion method, for example, in an impurity diffused from the inner wall of trench 8. Capacitor insulating film 12 is formed along the surface shape of first capacitor electrode 10, and second capacitor electrode 13 is formed by burying.

An etchback process is performed on an upper part of second capacitor electrode 13 and capacitor insulating film 12 so as to form collar oxide film 11. An upper inner wall of trench 8 is exposed and collar oxide film 11 is formed on the exposed part. A redundant portion of collar oxide film 11 is removed by etchback, and then arsenic-doped polysilicon, for example, is filled into the rest of trench 8. In this way, the trench capacitor is finished as shown in FIG. 3G.

It is possible to control the number of narrowed portions 9 to be provided in the trench 8 easily by adjusting the frequency of the narrowed portion formation process to be inserted. According to the method of manufacturing a semiconductor device including a trench capacitor according to this embodiment, it is possible to control not only the number of narrowed portions 9 but also depth positions for forming narrowed portions 9 freely.

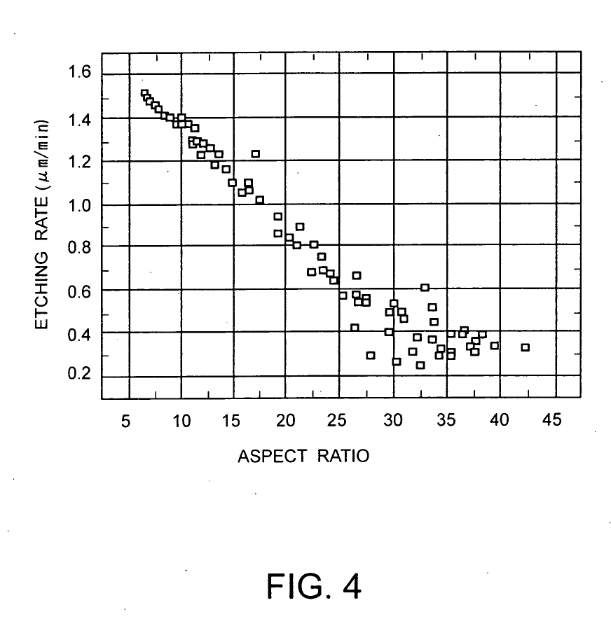

FIG. 4 is a graph showing dependency of the etching rate on the aspect ratio when forming the trench in the silicon substrate by etching. Along with the progress of the etching, etching deposit 17 is deposited inside the trench, more particularly, at a frontage thereof. The virtual aspect ratio of trench 8 is increased, and a decline in the etching rate occurs.

The control of the position for forming narrowed portion 9 is performed by converting the decline in the etching rate. For example, in order to form narrowed portions 9 at even intervals as shown in FIG. 3G, it is essential only to gradually extend the etching time in the course of main part formation processes. For example, when repeating the narrowed portion formation process and the main part formation process, the etching time for the narrowed portion formation process is fixed to 30 seconds, and the etching time for the main part formation process is started with one minute and is gradually extended for 15 second for each time of insertion of the narrowed portion formation process. The object of extension of the etching time is to supplement the decline in the etching rate. As a result, it is possible to form narrowed portions 9 at almost even intervals. The etching conditions in the respective processes herein are identical to those described previously.

In the method of manufacturing a semiconductor device including a trench capacitor according to this embodiment, narrowed portion 9 is formed on the trench sidewall in the course of the etching process for forming trench 8. Accordingly, it is possible to curtail the processes as compared to the conventional process of forming the irregular portions in a different process after formation of the trench. Therefore, the manufacturing method of this embodiment is excellent for mass production.

In a plurality of trench capacitors fabricated simultaneously by the method of manufacturing a semiconductor device including a trench capacitor according to the present invention, the shapes of trenches 8 are accurately controlled. As compared to the conventional case where the irregular portions are formed by natural formation, the semiconductor device manufactured according to this embodiment shows less variation in the shapes of the trenches. Accordingly, the semiconductor device manufactured according to this embodiment shows less variation in the electric capacity.

By forming the narrowed portions using the method of manufacturing a semiconductor device including a trench capacitor according to this embodiment, it is possible to align the direction of injection of etching sources into the trenches in a perpendicular direction to the semiconductor substrate. Accordingly, it is possible to obtain an excellent trench shape upon formation of a bottle-type trench. Effects of this embodiment will be described in the following.

The bottle-type trench is a trench formed by developing the etching so as to spread the trench diameter after formation of the taper of trench upper part 8a as shown in FIG. 3C. By forming this trench shape, it is possible to increase the surface area of the trench as compared to the case of developing the etching while maintaining the trench diameter immediately after formation of the taper. However, upon formation of such a bottle-type trench, the etching will not develop in the perpendicular direction to the semiconductor substrate as the etching progresses. As a result, it is known that the trench shape meanders. It is considered because there are many etching sources which are injected into the trench from various directions other than the perpendicular direction.

According to the method of manufacturing a semiconductor device including a trench capacitor according to this embodiment, narrowed portions 9 are provided in the course of formation of the trench. Accordingly, upon formation of the bottle-type trench, it is possible to restrict the number of etching sources, which are injected from various directions other than the perpendicular direction to the substrate, by narrowed portion 9. It is possible to develop the etching in the perpendicular direction to the substrate, and thereby to obtain an excellent trench shape. Here, it is preferable that the diameter of narrowed portion 9 is smaller than a diameter of an opening of the trench on the surface of the substrate in terms of restricting the number of etching sources to be injected from various directions other than the perpendicular direction to the substrate.

### SECOND EMBODIMENT

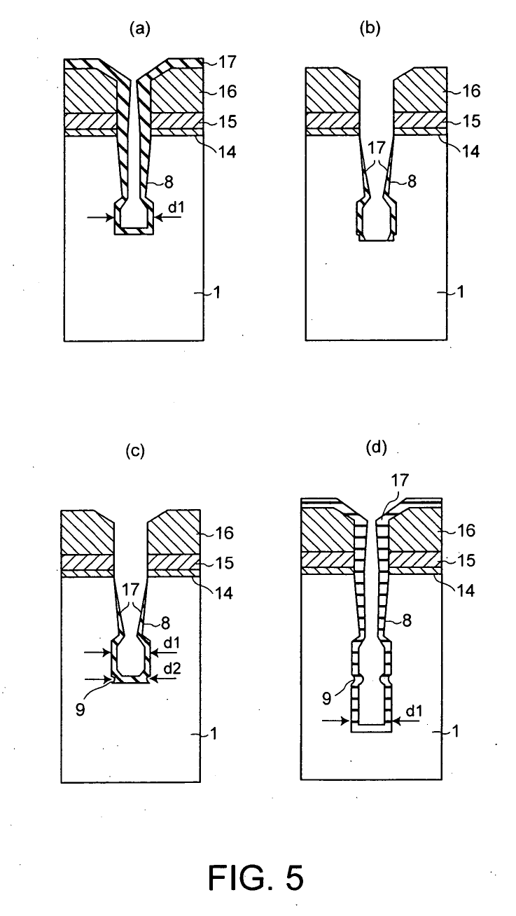

A method of manufacturing a semiconductor device including a trench capacitor according to a second embodiment of the present invention will be described with reference to FIGS. 5A to 5D. The structure of the semiconductor device including a trench capacitor manufactured by the manufacturing method according to this embodiment is identical to the structure described in the first embodiment with reference to FIG. 2 except that the number of narrowed portions 9 is reduced to one. Accordingly, description of the identical features will be omitted herein.

FIGS. 5A to 5D are cross-sectional views showing the method of manufacturing a semiconductor device including a trench capacitor according to the second embodiment of the present invention in the order of processes. The same reference numerals are used in FIG. 5 for the constituents corresponding to those illustrated in FIG. 3. Description will be omitted for the processes which are identical to those in the first embodiment.

The processes corresponding to FIGS. 3A to 3C of the first embodiment are performed on silicon substrate 1. As similar to the first embodiment, the process corresponding to FIG. 3C will be referred to as the main part formation process (the trench diameter of the main part will be also denoted as d1).

FIG. 5A is a cross-sectional view of a trench capacitor after performing the above-described processes. Etching deposit 17 of the reactant of silicon with etching sources is deposited inside the trench, especially on the upper part thereof. It is apparent that an effective aspect ratio of trench 8 is increased. An etching rate declines along with etching time, and the etching rate is reduced to about 0.25 ?m/min. at a depth of 5 ?m, for example.

Etching conditions are changed to 45 SCCM of NF₃, the pressure at 200 mTorr, and the excitation power at 500 W, for example, to facilitate removal of etching deposit 17. Under these conditions, the etching was continued for 30 seconds. As shown in FIG. 5B, along with the progress of the etching, etching deposit 17 which was deposited on the opening of trench 8 and on the central part at the bottom of the trench is removed. Etching deposit 17 remains unremoved on the side wall and the peripheral part at the bottom of the trench.

Etching deposit 17 functions as the protective film against etching. Accordingly, the etching rate varies between the central part and the peripheral part at the bottom of the trench reflecting the remaining amounts of etching deposit 17. In other words, the central part having a thinner protective film is etched more than the peripheral part. As a result, the etching progresses so as to narrow the trench diameter as similar to the first embodiment.

Next, the etching is performed under the etching conditions of 300 SCCM of HBr, 20 SCCM Of O₂, 7 SCCM of SF₆, the pressure at 200 mTorr, and the excitation power at 1600 W, for example, so as to spread the silicon in the diametrical direction. This etching is continued until the trench diameter spreads and reaches trench diameter d1. The etching time should be controlled in order to terminate this process when the trench diameter reaches trench diameter d1, for example. To be more precise, the etching time is set to 5 seconds.

As shown in FIG. 5C, narrowed portion 9 having trench diameter d2 being narrower than trench diameter d1 will be formed coaxially with trench 8 as similar to the first embodiment. The above-described processes performed after the main part formation process will be referred to as the narrowed portion formation process as similar to the first embodiment.

FIG. 5D is a cross-sectional view showing a second round of the main part formation process. After the above-described narrowed portion formation process, the etching is performed under the etching conditions of 300 SCCM of HBr, 22 SCCM of O_{2 ,} 7 SCCM of SF₆, the pressure at 200 mTorr, and the excitation power at 1600 W, for example, so as to hold the trench diameter substantially constant for forming the main part. Recovery of the etching rate is confirmed in comparison with that before the narrowed portion formation process. This is attributable to the fact that etching deposit 17 accumulated inside the trench is removed in the narrowed portion formation process and that the effective aspect ratio is thereby reduced.

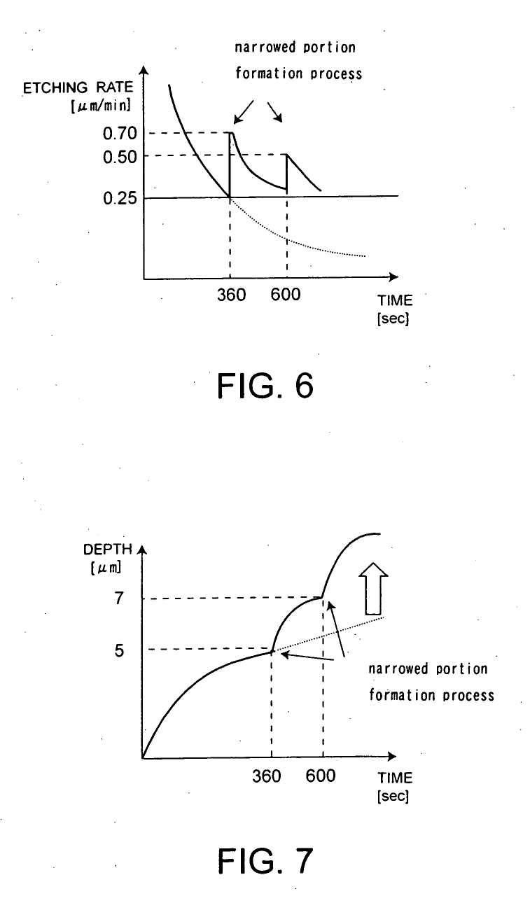

FIG. 6 is a graph schematically showing a relation between the processing time and the etching rate in the process for forming trench 8 according to the second embodiment of the present invention. FIG. 6 shows a case of introducing two rounds of the narrowed portion formation process as an example. It is apparent that the etching rate is increased when the narrowed portion formation process is introduced. The increase in the etching rate is smaller when introducing the second round of the narrowed portion formation process than the first round. This is because the aspect ratio of trench itself is changed along with the progress of the etching.

The narrowed portion formation process is introduced in appropriate timing so as to remove etching deposit 17. It is possible to maintain the etching rate without substantially deteriorating productivity by introducing the process in appropriate timing. As shown in FIG. 7, it is possible to form deeper trench 8 as compared to the case of not forming narrowed portions (illustrated with a dot line in FIG. 7). The appropriate timing for inserting the narrowed portion formation process may be set when the aspect ratio of trench 8 exceeds a predetermined value or when the etching rate falls below a predetermined rate.

In addition to the etching processes used in the first and second embodiments of the present invention, it is possible to use wet etching, or dry etching under etching conditions other than the etching conditions applied in the embodiments. In this way as well, it is possible to remove the etching deposit and thereby to suppress a decline in the etching rate. Since this embodiment can remove the etching deposit while forming the irregular portions, it can curtail the number of processes and is therefore excellent for mass production.

In this embodiment, it is possible to align the direction of injection of the etching sources into the trenches in the perpendicular -direction to the semiconductor substrate according to the narrowed portions are formed. Accordingly, it is possible to obtain an excellent trench shape upon formation of a bottle-type trench.

In this embodiment, fluorine-containing gas is used as the etching gas. It is also possible to obtain a similar result by use of gas which does not contain fluorine in a chemical composition thereof. However, the fluorine-containing gas can remove the etching deposit effectively when used as the etching gas. Accordingly, the fluorine-containing gas is suitable for the process for separating the etching deposit in this embodiment. Among a variety of fluorine-containing gas, fluorocarbon gas has the property of selectively etching the etching deposit being an oxide against silicon. Fluorocarbon gas is particularly useful as the etching gas to be applied to the process for separating the etching deposit in this embodiment.

### THIRD EMBODIMENT

This embodiment is characterized in that the etching rate of silicon is measured during the trench lower part formation process in the first or second embodiment. The narrowed portion formation process is inserted when the etching rate falls below a predetermined rate. The semiconductor device and the manufacturing method thereof according to this embodiment are identical to the above-described embodiments. Accordingly, description on the semiconductor device and the manufacturing method will be omitted herein.

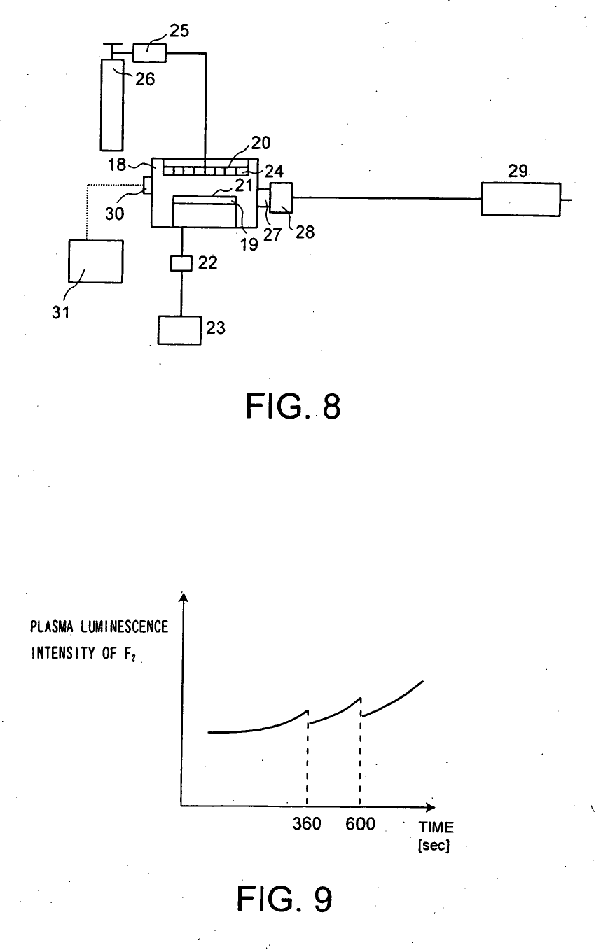

FIG. 8 schematically shows a structure of a plasma etching system used in this embodiment.

A process chamber 18 includes a plasma generation mechanism of a parallel plate type composed of a cathode electrode 19 and an anode electrode 20 which are opposed to each other. An unillustrated magnetic field application mechanism establishes a parallel magnetic field in process chamber 18. A processed substrate 21 is placed on cathode electrode 19. A high-frequency power source 23 is connected to cathode electrode 19 through a matching circuit 22.

A shower nozzle 24 for supplying process gas uniformly onto processed substrate 21 is incorporated in anode electrode 20. One or more gas cylinders 26 (only one gas cylinder is shown in the drawing) are connected to shower nozzle 24 through one or more flow rate control devices 25 (only one device is shown in the drawing). Gas cylinder 26 is respectively provided as supply sources of the process gas. A turbomolecular pump 28 is connected to process chamber 18 through a pressure adjustment valve 27. A dry pump 29 is connected to an outlet side of turbomolecular pump 28.

A luminescence monitor 30 for monitoring luminescence from the plasma is fitted to process chamber 18. For example, the etching rate is measured by monitoring plasma luminescence intensity of F₂. A controller system 31 is connected to luminescence monitor 30. Controller system 31 is configured to change the etching conditions based on a measurement result of the etching rate fed back from luminescence monitor 30.

A strong correlation exists between the etching rate and the plasma luminescence intensity of F₂. The plasma luminescence intensity of F₂ is gradually increased as the etching rate is decreased. This is because consumption of fluorine radicals is reduced as the etching rate is decreased. A decline in the etching rate is attributed to two reasons. Two reasons are an actual increase in the aspect ratio of trench 8 attributable to the progress of the etching and an effective increase in the aspect ratio attributable to deposition of etching deposit 17 inside the trench. FIG. 9 shows transition of the plasma luminescence intensity of F₂ relative to the etching time. The plasma luminescence intensity of F₂ is increased as the etching progresses.

When the luminescence intensity of F₂ is raised to predetermined luminescence intensity in the main part formation process, a signal obtained from luminescence monitor 30 is transmitted to controller system 31. In this event, the narrowed portion formation process for forming narrowed portion 9 simultaneously with removing etching deposit 17 is introduced. As a result, it is possible to introduce the narrowed portion formation process at the most efficient timing. It is possible to form the trench capacitor having excellent reproducibility and accuracy while maintaining the productivity.

### FOURTH EMBODIMENT

As similar to the third embodiment, this embodiment is characterized in that the etching rate of silicon is measured during the trench lower part formation process. The narrowed portion formation process is inserted when the etching rate falls below the predetermined rate. This embodiment adopts a method of measuring the etching rate which is different from the third embodiment.

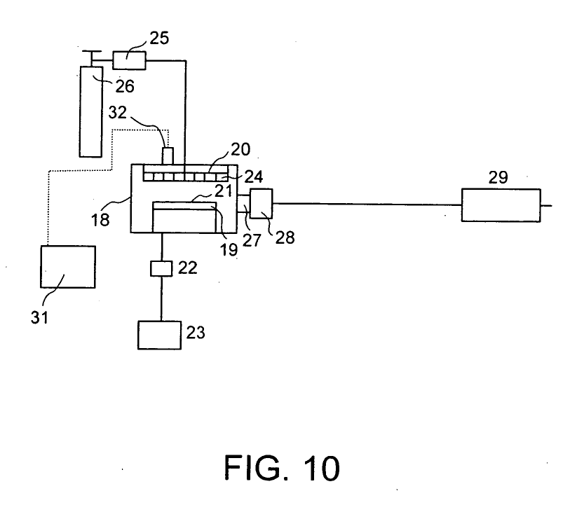

FIG. 10 schematically shows a structure of a plasma etching system used in this embodiment. The same reference numerals are used for representing common constituents to FIG. 8, and description on the common constituents will be omitted herein. A difference from the etching system used in the third embodiment is that a film-thickness monitor 32 for measuring a film thickness of silicon oxide film 16 which is an etching mask (illustrated in FIGS. 5A to 5D) is fitted. Film-thickness monitor 32 may fit instead of the luminescence monitor.

A correlation is observed between the etching rate of silicon substrate 1 and the etching rate of silicon oxide film 16. When the etching rate of the silicon is decreased, the amount of an etching product such as SiF₄ is reduced. The amount of etching deposit 17 to be deposited on silicon oxide film 16 is reduced by a reaction between SiF₄ and active oxygen. As a result, the etching rate of silicon oxide film 16 is increased. Considering this correlation, it is possible to calculate the etching rate of the silicon from the etching rate of silicon oxide film 16 by measuring the film thickness of silicon oxide film 16 with film-thickness monitor 32.

Means for measuring the film thickness of silicon oxide film 16 includes measurement of reflected light intensity from silicon oxide film 16, for example. Reflected light from the top surface of silicon oxide film 16 and reflected light from the bottom surface thereof have different phases. Accordingly, intensity of such diffraction rays fluctuates in accordance with the film thickness of silicon oxide film 16.

In this embodiment, the etching rate of the silicon is decreased as the etching of trench 8 progresses. Accordingly, a rate of reduction in the film thickness of silicon oxide film 16 (the etching rate of silicon oxide film 16) is gradually increased.

When the etching rate of silicon oxide film 16 reaches a predetermined value in the main part formation process, in other words, when the etching rate of the silicon is reduced to a predetermined value in the main part formation process, a signal obtained from film-thickness monitor 32 is transmitted to controller system 31. In this event, the narrowed portion formation process for forming narrowed portion 9 simultaneously with removing etching deposit 17 is introduced. As a result, it is possible to introduce the narrowed portion formation process at the most efficient timing. It is possible to form trench 8 having excellent reproducibility and accuracy while maintaining the productivity.

Various modifications can be made in embodying the embodiments of the present invention without departing from the gist thereof. For example, the upper part of the trench may be formed into a perpendicular shape instead of the tapered shape. The lower part of the trench except the main parts may be formed into a tapered shape instead of the substantially perpendicular shape.

In each of the embodiments of the present invention, a trench comprises a trench upper part and a trench lower part, and the trench lower part comprises main parts and narrowed portions. However, when the upper part of the trench is formed into a perpendicular shape instead of the tapered shape, the etching conditions in the main parts formation process and the etching conditions in the upper part formation process may be made the same. In this event, the upper part may be included to the main parts. Moreover, the upper part does not need to be formed.

In the semiconductor device containing trench capacitors according to each of the embodiments of the present invention, second capacitor electrode 13 is connected to source diffusion layer 2 disposed adjacently to the trench capacitor. However, it is also possible to connect first capacitor electrode to the diffusion layer instead.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A semiconductor device including a trench capacitor, comprising:
a semiconductor substrate;
a trench provided on the semiconductor substrate, the trench including a narrowed portion and a main part having substantially straight side walls in terms of a perpendicular cross section to a surface of the substrate, a diameter of the narrowed portion being coaxially smaller than a diameter of the trench at the main part;
a first capacitor electrode provided in the semiconductor substrate so as to surround the trench inclusive of the narrowed portion;
a capacitor insulating film provided along a surface of the first capacitor electrode; and
a second capacitor electrode provided inside the trench, the second capacitor electrode being opposed to the first capacitor electrode through the capacitor insulating film.

2. The semiconductor device according to claim 1, further comprising:
a first diffusion layer connected to any one of the first capacitor electrode and the second capacitor electrode, the first diffusion layer being provided on the semiconductor substrate;
a second diffusion layer provided on the semiconductor substrate at a distance from the first diffusion layer; and
a gate electrode provided on the semiconductor substrate through an insulating film in a space between the first diffusion layer and the second diffusion layer.

3. The semiconductor device according to claim 1,
wherein the main parts and the narrowed portions are alternately formed.

4. The semiconductor device according to claim 1,
wherein the diameter of the narrowed portion is smaller than a diameter of an opening of the trench on the surface of the substrate.

5. The semiconductor device according to claim 1,
wherein the trench comprises a trench upper part and a trench lower part, and
the narrowed portion is formed at the trench lower part.

6. The semiconductor device according to claim 5,
wherein the trench upper part is a tapered trench.

7. A semiconductor device including trench capacitors, comprising:
a semiconductor substrate;
a first trench provided on the semiconductor substrate, the first trench including a narrowed portion and a main part having substantially straight side walls in terms of a perpendicular cross section to a surface of the substrate, a diameter of the narrowed portion being coaxially smaller than a diameter of the first trench at the main part;
a second trench provided on the semiconductor substrate at a distance from the first trench, the second trench having substantially the same depth and substantially the same diameter as the first trench, the second trench including a narrowed portion having substantially the same diameter and being provided in substantially the same depth position as the narrowed portion of the first trench;
a first capacitor electrode respectively provided in the semiconductor substrate in a position corresponding to each of the first trench and the second trench so as to surround each of the first trench and the second trench inclusive of the narrowed portion;
a capacitor insulating film respectively provided along a surface of the first capacitor electrode of each of the first trench and the second trench; and
a second capacitor electrode respectively provided inside each of the first trench and the second trench, the second capacitor electrode being opposed to the first capacitor electrode through the capacitor insulating film.

8. The semiconductor device according to claim 7, further comprising:
a first diffusion layer connected to any one of the first capacitor electrode and the second capacitor electrode provided at the first trench, the first diffusion layer being provided on the semiconductor substrate;
a second diffusion layer provided on the semiconductor substrate at a distance from the first diffusion layer;
a first gate electrode provided on the semiconductor substrate through an insulating film in a space between the first diffusion layer and the second diffusion layer;
a third diffusion layer connected to any one of the first capacitor electrode and the second capacitor electrode provided at the second trench, the third diffusion layer being provided on the semiconductor substrate;
a fourth diffusion layer provided on the semiconductor substrate at a distance from the third diffusion layer; and
a second gate electrode provided on the semiconductor substrate through an insulating film in a space between the third diffusion layer and the fourth diffusion layer.

9. The semiconductor device according to claim 7,
wherein the main parts and the narrowed portions are alternately formed.

10. The semiconductor device according to claim 7,
wherein the diameter of the narrowed portion is smaller than a diameter of an opening of the trench on the surface of the substrate.

11. The semiconductor device according to claim 7,
wherein each of the first trench and the second trench comprises a trench upper part and a trench lower part, and
the narrowed portion is formed at the trench lower part.

12. The semiconductor device according to claim 11,
wherein the trench upper part is a tapered trench.

13. A method of manufacturing a semiconductor device including a trench capacitor comprising:
forming a mask pattern on an upper surface of a semiconductor substrate; and
forming a trench on the semiconductor substrate while using the mask pattern as an etching mask,
wherein forming the trench includes forming a main part of a trench by first anisotropic etching process and forming a narrowed portion in which a diameter of the main part of the trench is coaxially reduced by second anisotropic etching process in which etching conditions differ from the first anisotropic etching process.

14. The method according to claim 13,
wherein an etching deposit deposited inside the trench is removed-in forming the narrowed portion.

15. The method according to claim 13,
wherein forming the narrowed portion is performed when an aspect ratio of the trench exceeds a predetermined value in forming the trench.

16. The method according to claim 13,
wherein forming the narrowed portion is performed when an etching rate falls below a predetermined value in forming the trench.

17. The method according to claim 16,
wherein plasma etching is performed as the anisotropic etching, and
the etching rate is measured by monitoring plasma luminescence intensity during the plasma etching in forming the trench.

18. The method according to claim 16,
wherein the etching rate is determined based on a film thickness of the etching mask during forming the main part of the trench, which is obtained by measuring reflected light intensity from the etching mask in forming the trench.

19. The method according to claim 13,
wherein gas having a chemical composition containing fluorine is used as the etching gas in forming the narrowed portion.

20. The method according to claim 19,
wherein the gas having the chemical composition containing fluorine is fluorocarbon gas.
